(19) United States
(12) Patent Application Publication
(10) Pub. No.: US 2018/0288887 A1
(43) Pub. Date: Oct. 4, 2018

(54) ELECTRONIC DEVICE

(71) Applicant: Asahi Glass Company, Limited, Chiyoda-ku (JP)

(72) Inventors: Naoki OKAHATA, Chiyoda-ku (JP); Yuki Aoshima, Chiyoda-ku (JP); Yuki Akama, Chiyoda-ku (JP); Misa Inamoto, Chiyoda-ku (JP); Takashi Shibuya, Chiyoda-ku (JP)

(73) Assignee: Asahi Glass Company, Limited, Chiyoda-ku (JP)

(21) Appl. No.: 15/842,219

(22) Filed: Dec. 14, 2017

(30) Foreign Application Priority Data
Mar. 30, 2017 (JP) 2017-067643

(51) Int. Cl. H05K 5/00; H05K 5/03

(52) U.S. Cl. CPC H05K 5/0017; B82Y 30/00; H05K 2201/10151; H05K 5/03

(57) ABSTRACT

An electronic device includes a chassis having an opening; a display unit and a touch panel configured to be housed in the chassis; and a cover glass arranged on the opening having a main surface region configured to accommodate a display from the display unit and an input to the touch panel, and an end surface region corresponding to a side surface of the chassis. The end surface region includes a first region having a first surface roughness and configured to accommodate the input to the touch panel, and a second region having a second surface roughness that is different from the first surface roughness.

### CROSS-REFERENCE TO RELATED APPLICATION

The present application is based on and claims benefit of priority under 35 U.S.C. § 119 of Japanese Patent Application No. 2017-067643, filed Mar. 30, 2017. The contents of the application are incorporated herein by reference in their entirety.

### BACKGROUND OF THE INVENTION

### 1. Field of the Invention

The disclosure herein generally relates to an electronic device provided with a display unit and a touch panel.

### 2. Description of the Related Art

An electronic device, such as a smartphone or a tablet type computer, often includes a display unit and a touch panel. Typically, a cover glass is attached to an outer surface of such an electronic device.

Recently, an increase in size of a display unit of an electronic device has been required. In order to respond to the requirement, PCT international application publication No. WO 2013/048881 discloses an electronic apparatus provided with a display unit on a side surface. Moreover, U.S. Patent application publication No. 2013/0300697 discloses a mobile terminal having a curved surface display unit on a side surface.

### SUMMARY OF THE INVENTION

When turning on or off a power of an electronic device, or turning up or down a volume of sound, an operation may be desired to be performed by a tactile sense from a user's hand, without identifying the electronic device by a visual sense.

The electronic device disclosed in PCT international application publication No. WO 2013/048881 or U.S. Patent application publication No. 2013/0300697 is not provided with a physical button or the like, because a side surface region of the display unit is used as a region for displaying and sensing.

Thus, in the electronic device disclosed in PCT international application publication No. WO 2013/048881 a dummy button member or a feedback component is arranged in the side surface region in order to provide a user with tactile button identification.

However, in such a case, a physical structure such as a button member is required. Moreover, the button member projects from an end surface of the electronic device, and is not preferable in design. Furthermore when a chassis and the display unit are configured integrally, applying the above-described feature, i.e. forming a physical structure on the end surface, becomes difficult.

Moreover, the electronic device causes a user to identify a position of such a button by a feedback element that provides the user with a vibration, sounds or the like. However, a mechanism required for the operation becomes complicated.

In the electronic device disclosed in U.S. Patent application publication No. 2013/0300697, because a front surface region of the display unit and a side surface region of the display unit have curved shapes and are continuous, it may be difficult for a user to identify a boundary between the regions. Particularly, when an angle between the front surface region and the side surface region is great, it becomes difficult to identify the side surface region. Thus, it becomes difficult to identify an operation position on the side surface region by a tactile sense.

The present invention, in consideration of the above-described problem, aims at providing an electronic device that enables a user to identify an operation position in an end surface region of a cover glass with a simple structure.

According to an aspect of the present invention, an electronic device includes

a chassis having an opening;

a display unit and a touch panel configured to be housed in the chassis; and

a cover glass arranged on the opening, having a main surface region configured to accommodate a display from the display unit and an input to the touch panel, and an end surface region corresponding to a side surface of the chassis,

the end surface region including a first region having a first surface roughness and configured to accommodate the input to the touch panel, and a second region having a second surface roughness that is different from the first surface roughness.

According to the electronic device of the present invention, a user can identify the operation position in the end surface region of the cover glass by a tactile sense with a simple structure. Moreover, it becomes possible to provide a grip feeling for the end surface region of the cover glass, and to thereby reduce the possibility of the electronic device becoming unexpectedly dropped and damaged.

### BRIEF DESCRIPTION OF THE DRAWINGS

Other objects and further features of embodiments will become apparent from the following detailed description when read in conjunction with the accompanying drawings, in which:

FIG. 1 is a perspective view schematically depicting an example of an electronic device according to a first embodiment;

FIG. 2 is a perspective view schematically depicting an example of an electronic device according to a variation of the first embodiment; and

FIG. 3 is a perspective view schematically depicting an example of an electronic device according to a second embodiment.

### DETAILED DESCRIPTION OF THE PREFERRED EMBODIMENTS

In the following, embodiments of the present invention will be described with reference to the accompanying drawings. The present invention is explained by the following embodiments. However, without departing from the scope of the present invention, various variations may be made by numerous methods, and embodiments other than the embodiments described may be used. Therefore, all variations within the scope of the present invention are included in claims. In the following, in the drawings, parts indicated by the same symbol are basically similar elements having similar functions.

### First Embodiment

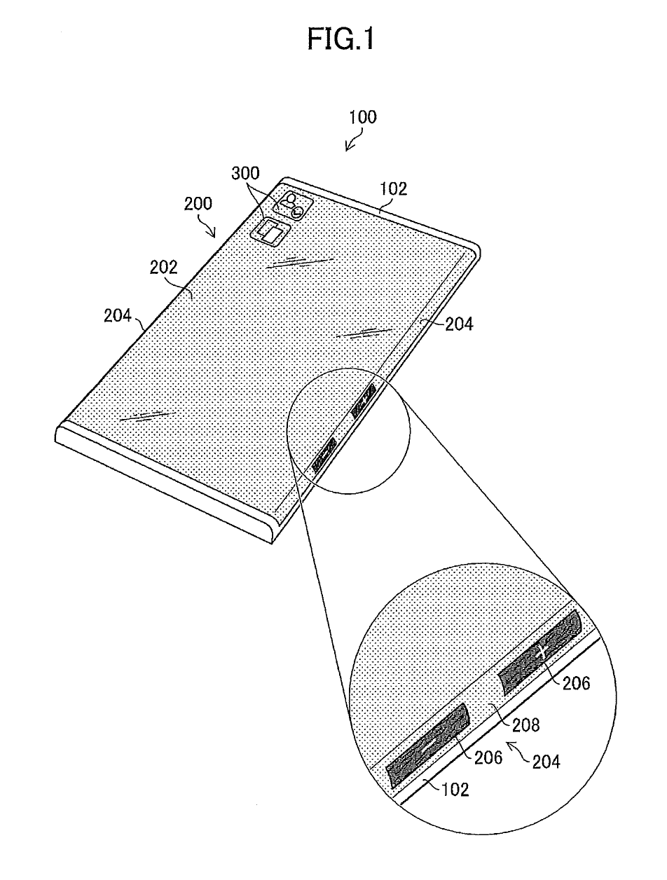

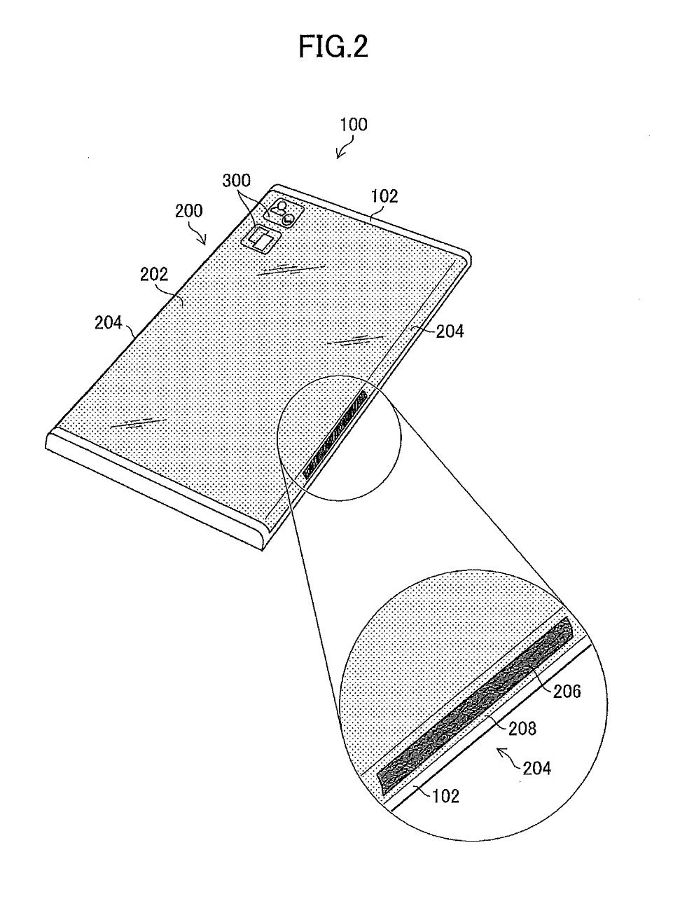

An electronic device according to a first embodiment will be described with reference to FIG. 1 and FIG. 2. FIG. 1 is a perspective view depicting an example of an electronic device according to an embodiment, represented by a smartphone. FIG. 2 is a perspective view depicting an example of an electronic device according to a variation of the first embodiment.

As illustrated in FIG. 1, the electronic device 100 includes a chassis 102 having an opening, and a cover glass 200 arranged so as to cover the opening of the chassis 102. In the embodiment, the chassis 102 with an integrated structure is illustrated as an example. The structure of the chassis 102 is not particularly limited to this, and may be configured of a plurality of members.

A material of a member configuring the chassis 102 may be a glass, a resin or a metal. Moreover, when the chassis 102 is configured of a plurality of members, the respective members may be made of the same material, or different materials.

As illustrated in FIG. 1, the cover glass 200 includes a main surface region 202, and two end surface regions 204 corresponding to side surfaces of the chassis 102. The main surface region 202 and the end surface regions 204 are exposed portions of the cover glass 200 from the chassis 102. Note that, the embodiment illustrates an example of a mode in which the main surface region 202 and the end surface regions 204 are continuous (i.e. provided continuously). The present invention is not limited to this. For example, a glass plate configuring the main surface region 202 and glass plates configuring the end surface regions 204 may be separated from each other.

The main surface region 202 has a flat shape, and is a region that occupies the greatest area of the cover glass 200. A flatness of the main surface region 202 is only required to be an extent that does not block the function of the electronic device 100.

In the embodiment, two end surface regions 204 have shapes of curved surfaces that are continuous to the main surface region 202 (i.e. provided continuously). The shape of curved surface means that a cross section of the end surface region 204 cut along a direction continuous with the main surface region 202 has a shape of a curve. The shape of a curve includes, for example, a shape of an arc or a shape of an elliptic arc.

A thickness of the cover glass 200 is, for example, preferably 3 mm or less, more preferably 0.2 mm or more and 2.0 mm or less, and further preferably 0.3 mm or more and 1.5 mm or less. When the thickness of the cover glass 200 is greater than 3 mm, there is concern that a weight increases and a weight saving becomes difficult, and a raw material cost increases. Moreover, when the thickness of the cover glass 200 is less than 0.2 mm, a stiffness of the cover glass 200 decreases, and there is concern that the cover glass 200 cannot perform the function of protection. The thickness of the cover glass 200 means a thickness of the thickest part of the cover glass 200.

The cover glass 200 is shaped through a floating method, a fusion method or the like. The cover glass 200 is configured of a soda lime silicate glass, alumino silicate glass, alkali-free glass, or the like. The cover glass 200 may be a chemically strengthened cover glass that was subjected to a chemical strengthening process, or may be a non-strengthened cover glass. In the case of the chemically strengthened cover glass, the cover glass 200 includes alkali metal or alkali earth metal.

In the present application, the “chemical strengthening process” collectively means a technique of immersing a glass plate that is to be a base plate for a cover glass into a molten salt including alkali metal to replace alkali metal (ions) with a small atomic diameter existing on the outermost surface of the glass plate by alkali metal (ions) with a great atomic diameter existing in the molten salt. According to the “chemical strengthening process”, on a surface of the processed glass plate, alkali metal (ions) with a greater atomic diameter than the atoms before the chemical strengthening process is arranged. Thus, a compressive stress layer can be formed on a surface of the glass plate, and the strength of the glass plate is improved.

For example, when the glass plate includes sodium (Na), at the time of the chemical strengthening process in molten-salt (e.g. nitrate salt), sodium is replaced by, for example, potassium (K). Alternatively, when the glass plate includes, for example, lithium (Li), at the time of the chemical strengthening process, lithium may be replaced in the molten-salt (e.g. nitrate salt) by, for example, sodium (Na) and/or potassium (K).

The chassis 102 of the electronic device 100 includes an empty space inside the chassis 102. In the space of the chassis 102, a display unit (not shown) and a touch panel (not shown) are housed. The display unit provides information to a user by displaying characters, pictures or the like.

As a display unit, a liquid crystal display unit, an organic light emitting diode unit or the like can be used. For example, the liquid crystal display unit is configured of a TFT (Thin Film Transistor) substrate including a glass substrate, a resin substrate or the like, a CF (Color Filter) substrate, and a liquid crystal layer sandwiched by the TFT substrate and the CF substrate.

The display unit is arranged at a position of the cover glass 200 facing the main surface region 202. Because the main surface region 202 accommodates a display from the display unit, the display from the display unit is provided to a user via the main surface region 202 of the cover glass 200. The user obtains information by identifying the display by a visual sense. As illustrated in FIG. 1, for example, in the main surface region 202 of the cover glass 200, an icon 300 is displayed.

The display unit preferably has a size of 90% or more of the size of the main surface region 202 of the cover glass 200. By increasing the size of the display unit of the electronic device, the amount of information that can be displayed in the main surface region 202 increases.

A touch panel (also referred to as a touch screen) detects values of coordinates of a position on the touch panel where a user touches. As a touch panel, for example, an electrostatic capacitance type touch panel can be used. The electrostatic capacitance type touch panel is configured of, for example, a substrate for touch panel, and a transparent ITO (Indium Tin Oxide) electrode arranged on the substrate for touch panel in a pattern shape.

The touch panel is inserted between the main surface region 202 of the cover glass 200 and the display unit. In the embodiment, because the main surface region 202 of the cover glass 200 accommodates an input to the touch panel, the touch panel can detect a position where a user touches via the main surface region 202. A signal in response to the position in the main surface region 202 where the touch input is performed is input to a control device (not shown). The control device performs a process according to the input signal.

The touch panel may be integrated with the cover glass 200, or may be separated from the cover glass 200. When the touch panel is integrated with the cover glass 200, a number of components can be reduced and the electronic device 100 can be made thinner, which is preferable.

In the electronic device 100 according to the embodiment, the end surface region 204 of the cover glass 200 includes a first region 206 having a first surface roughness, and a second region 208 having a second surface roughness that is different from the first surface roughness. The touch panel is arranged at a position corresponding to the first region 206. In the embodiment, because the first region 206 having the first surface roughness accommodates an input to the touch panel, when a user touches the first region 206, the touch panel can detect that the touch panel is touched. A signal in response to the position in the first region 206 where the touch input is performed is input to the control device (not shown). The control device performs a process according to the input signal. The first region 206 functions as an input element (input means, e.g. a button or a switch) to the electronic device 100.

Because the second region 208 having the second surface roughness does not accommodate an input to the touch panel, even if the user touches the second region 208, the touch panel does not detect the touch input. The second region 208 does not function as an input element (button, switch or the like) to the electronic device 100.

The first region 206 and the second region 208 have a different surface roughness. When the user touches the end surface region 204, the user can identify a position of the first region 206 that is the input element by a tactile sense, without relying on visual sense. Thus, the user can operate the electronic device 100 easily.

In FIG. 1, in order to easily distinguish the first region 206 and the second region 208, both regions are illustrated with different background patterns. However, the background patterns of the regions are not required to be different.

In the embodiment, an operation by a tactile sense is enabled by a simple configuration such that surface roughness of the first region 206 and surface roughness of the second region 208 in the end surface region 204 are made different, without using an additional structure, such as a button member or a feedback element.

Because the electronic device 100 according to the embodiment is not provided with a projecting part such as a button member, it is preferable in design. Moreover, the configuration of the embodiment can be easily applied to the case where the chassis 102 and the cover glass 200 are integrated.

Moreover, according to the embodiment, even if the main surface region 202 and the end surface region 204 are made of the same material and have curved surfaces which are smoothly continued, the first region 206 and the second region 208 in the end surface region 204 can be identified by a tactile sense.

An action of the above-described configuration will be described with reference to FIG. 1. In the embodiment, assume that a user of the electronic device 100 executes an application program for playing music. Each of the two first regions 206 in the end surface region 204 is provided with a function as an input element for controlling a sound volume of the electronic device 100. One of the two first regions 206 is indicated by a “+” mark and is provided with a function of increasing sound volume. Moreover, the other of the two first regions 206 is indicated by a “−” mark and is provided with a function of decreasing sound volume.

For example, the user can identify the first region 206 indicated by “+” in the end surface region 204 of the cover glass 200 and the first region 206 indicated by “−” by a tactile sense, without identifying the electronic device 100 by a visual sense. The user can easily increase and decrease a sound volume without taking out the electronic device 100.

In the embodiment, because the end surface region 204 accommodates a display from the display unit, information from the display unit can be displayed on the end surface region 204. As illustrated in FIG. 1, in the two first regions 206, the “+” mark and the “−” mark are displayed as the information from the display unit, respectively. By displaying the information from the display unit, in the case of taking out the electronic device 100, the user can identify the first region 206 and the second region 208 by a visual sense.

Note that because the end surface region 204 accommodates a display from the display unit, the end surface region 204 can display information from the display unit. For example, a notice from an application program can be displayed on the end surface region 204.

In the electronic device 100, a function given to the first region 206 may be changed for each application program. For example, in the case of executing an application program for a camera, functions of zooming in and of zooming out can be given to the two first regions 206, respectively.

In the embodiment, the case where the end surface region 204 responds to the display unit has been described. However, the end surface region 204 is not required to respond to the display unit, as long as the first region 206 and the second region 208 of the end surface region 204 can be identified by a tactile sense.

The surface roughness of the first region 206 (first surface roughness) in the embodiment is preferably nm or more and 300 nm or less. In the present application, the surface roughness is an arithmetic average roughness described in the Japanese Industrial standards (JIS B 0601). By setting the first surface roughness to 5 nm or more and 300 nm or less, it becomes easier to identify the first region 206 as a button by a tactile sense.

By performing a roughening treatment for a region that is to be a first region of the end surface region 204 of the cover glass 200, a rugged structure with a surface roughness of 5 nm or more and 300 nm or less can be formed on a surface of the first region 206. For example, in the roughening treatment, an etching treatment is performed on a surface of the end surface region 204. The etching treatment includes a chemical etching, a physical etching, or the like. In the case of the chemical etching, any of a dry etching and a wet etching can be used. In the dry etching, for example, a processing gas including hydrogen fluoride (HF) gas may be used.

A temperature of the etching treatment is not particularly limited, but falls, normally, within a range of 400° C. to 800° C. The temperature of the etching treatment falls preferably within a range of 500° C. to 700° C., and more preferably within a range of 500° C. to 650° C.

The processing gas may contain, in addition to hydrogen fluoride gas, carrier gas and diluting gas. The carrier gas and diluting gas are not particularly limited. As carrier gas and diluting gas, for example, nitrogen, argon and/or the like is used. Moreover, water may be added.

A concentration of hydrogen fluoride gas in the processing gas is not particularly limited, as long as a region that is to be a first region of the end surface region 204 of the cover glass 200 is properly subjected to an etching treatment. The concentration of hydrogen fluoride gas in the processing gas falls within, for example, a range of 0.1 vol % or more and 10 vol % or less, preferably a range of 0.3 vol % or more and 5 vol % or less, and more preferably a range of 0.5 vol % or more and 4 vol % or less. At this time, the concentration of hydrogen fluoride gas in the processing gas (vol %) is obtained by (flow rate of hydrogen fluoride gas/(flow rate of hydrogen fluoride gas+flow rate of carrier gas+flow rate of diluting gas))×100.

The second region 208 preferably has a surface roughness different from the surface roughness of the first region 206 that is 5 nm or more and 300 nm or less. The surface roughness of the second region 208 (second surface roughness) is preferably 0.05 nm or more and 20 nm or less, and more preferably 2 nm or more and 15 nm or less. By setting the second surface roughness to be 0.05 nm or more and 20 nm or less, the grip feeling when the user holds the end surface region 204 is enhanced. The first surface roughness is preferably greater than the second surface roughness by a surface roughness of 5 nm or more. Thus, while the grip feeling of the electronic device 100 is improved, the first region 206 can be identified by a tactile sense.

[Variation of First Embodiment]

A variation of the first embodiment will be described. To a configuration similar to the first embodiment illustrated in FIG. 1, the same reference numeral is assigned and an explanation thereof may be omitted.

As illustrated in FIG. 2, an electronic device 100 according to a variation of the first embodiment includes a chassis 102; and a cover glass 200 having a main surface region 202 and end surface regions 204 corresponding to side surfaces of the chassis 102. The cover glass 200 is arranged on an opening of the chassis 102.

Different from the first embodiment, in the variation of the first embodiment, a single first region 206 is arranged in the end surface region 204. According to a function given to the first region 206, a size of the first region 206 is properly determined.

For example, a function as a button for controlling a sound volume or turning on/off a power of the electronic device 100 can be given to the first region 206. Moreover, in response to an application program that performs a display on the main surface region 204, an item for facilitating utilization of the application program can be displayed in the first region 206. For example, when an application program for photographs is executed in the electronic device 100 and a photograph image is displayed in the main surface region 204, a plurality of thumbnail images can be displayed in the first region 206.

Moreover, when an application program for electronic mail is executed in the electronic device 100 and an input screen is displayed in the main surface region 204, a plurality of pictographs or the like can be displayed in the first region 206.

Because the first region 206 and the second region 208 have different surface roughness, when a user touches the end surface region 204, the user can identify a position of the first region 206 that is an input element by a tactile sense, without relying on visual sense. The user can operate the electronic device 100 easily.

The first embodiment and the variation of the first embodiment can be combined. For example, two first regions 206 may be arranged in one of the end surface regions 204 of the electronic device 100, and one first region 206 may be arranged in the other end surface region 204. A number of the first regions 206 arranged in the end surface region 204 and a position of arrangement thereof are not particularly limited.

### Second Embodiment

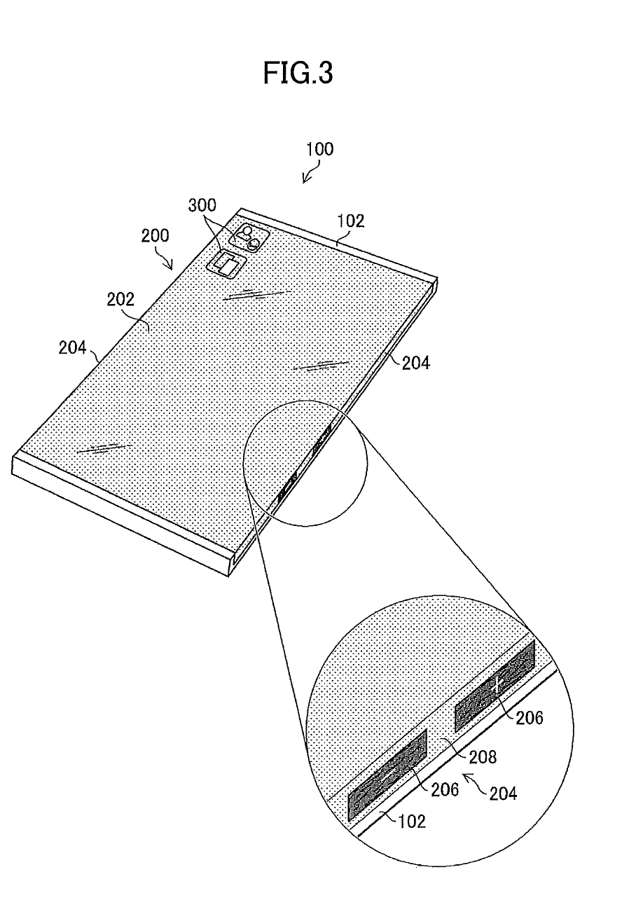

An electronic device according to a second embodiment will be described with reference to FIG. 3. To a configuration similar to that of the electronic device according to the first embodiment, the same reference numeral is assigned and an explanation thereof may be omitted.

As illustrated in FIG. 3, the electronic device 100 according to the second embodiment includes a chassis 102; and a cover glass 200 having a main surface region 202 and an end surface region 204. The cover glass 200 is arranged on an opening of the chassis 102. The end surface region 204 has a first region 206 with a first surface roughness and a second region 208 with a second surface roughness that is different from the first surface roughness.

In the electronic device 100 according to the second embodiment, different from the first embodiment, the end surface region 204 corresponding to a side surface of the chassis 102 has a flat shape. The flat shape means that a cross section of the end surface region 204 has a straight shape or an approximately straight shape. That is, the flatness of the end surface region 204 is only required to be an extent that is required for an end surface region 204 of a cover glass 200 of an electronic device 100.

In the same way as the first embodiment, in the electronic device 100 according to the second embodiment, the first region 206 and the second region 208 have different surface roughness. When a user touches the end surface region 204, the user can identify a position of the first region 206 that is an input element by a tactile sense, without relying on a visual sense. The user can operate the electronic device 100 easily.

In the same way as the first embodiment, the cover glass 200 may be a chemically strengthened cover glass. Moreover, the first surface roughness of the first region 206 can be set to be 5 nm or more and 300 nm or less. The second surface roughness of the second region 208 can be set to be 0.05 nm or more and 20 nm or less. The cover glass 200 is preferably coated with a coating film.

In the embodiments, as an electronic device, a smartphone has been exemplified. However, the present application is not limited to the embodiments. The electronic device may include a tablet type computer or the like.

### REFERENCE SIGNS LIST

100 electronic device
102 chassis
200 cover glass
202 main surface region
204 end surface region
206 first region
208 second region
300 icon

What is claimed is:

1. An electronic device comprising:
a chassis having an opening;
a display unit and a touch panel configured to be housed in the chassis; and
a cover glass arranged on the opening having a main surface region configured to accommodate a display from the display unit and an input to the touch panel, and an end surface region corresponding to a side surface of the chassis,
wherein the end surface region includes a first region having a first surface roughness and configured to accommodate the input to the touch panel, and a second region having a second surface roughness that is different from the first surface roughness.

2. The electronic device according to claim 1,
wherein the first surface roughness is greater than the second surface roughness by a surface roughness of 5 nm or more.

3. The electronic device according to claim 1,
wherein the first surface roughness is 5 nm or more and 300 nm or less.

4. The electronic device according to claim 1,
wherein the second surface roughness is 0.05 nm or more and 20 nm or less.

5. The electronic device according to claim 1,
wherein the main surface region and the end surface region of the cover glass are provided continuously.

6. The electronic device according to claim 1,
wherein the end surface region has a curved surface shape.

7. The electronic device according to claim 1,
wherein the end surface region has a flat surface shape.

8. The electronic device according to claim 1,
wherein the end surface region accommodates the display from the display unit.
